(19) United States
(12) Patent Application Publication
(10) Pub. No.: US 2018/0114804 A1
(43) Pub. Date: Apr. 26, 2018

(54) HIGH RELIABILITY HOUSING FOR A SEMICONDUCTOR PACKAGE

(71) Applicant: SEMICONDUCTOR COMPONENTS INDUSTRIES, LLC, Phoenix, AZ (US)

(72) Inventor: Yu-Te Hsieh, Taoyuan City (TW)

(73) Assignee: SEMICONDUCTOR COMPONENTS INDUSTRIES, LLC, Phoenix, AZ (US)

(21) Appl. No.: 15/850,031

(22) Filed: Dec. 21, 2017

Related U.S. Application Data
(63) Continuation-in-part of application No. 15/679,373, filed on Aug. 17, 2017.
Application No. 15/679,373 is a division of application No. 15/175,226, filed on Jun. 7, 2016, now abandoned.
(60) Provisional application No. 62/302,227, filed on Mar. 2, 2016.

(51) Int. Cl. H01L 27/146; H01L 25/16

(52) U.S. Cl. CPC H01L 27/14618; H01L 27/1469; H01L 27/14685; H01L 27/14678; H01L 27/14643; H01L 27/14636; H01L 27/14634; H01L 27/14625; H01L 25/167

(57) ABSTRACT

Implementations of semiconductor packages may include: a substrate including a first side and a second side and an image signal processor (ISP) including a first side and a second side where first side of the ISP is coupled to the first side of the substrate. A first mold compound may encapsulate the second side of the ISP and an image sensor having a first side and a second side. The first side of the image sensor is coupled to the first mold compound which may be substantially coextensive with a perimeter of the first side of the image sensor. Implementations of image sensor packages may also include an optically transmissive cover and a polymeric compound encapsulating a portion of the substrate, the first mold compound, the image sensor, and a portion of the optically transmissive cover.

### CROSS REFERENCE TO RELATED APPLICATIONS

This document claims the benefit of the filing date of U.S. Provisional Patent Application 62/302,227, entitled “High Reliability Housing for a Semiconductor Package” to Yu-Te Hsieh which was filed on Mar. 2, 2016, the disclosure of which is hereby incorporated entirely herein by reference.

This application is also a continuation-in-part application of the earlier U.S. Utility patent application to Yu-Te Hsieh entitled “High Reliability Housing for a Semiconductor Package,” application Ser. No. 15/679,373, filed Aug. 17, 2017, which is a divisional application of the earlier U.S. Utility patent application to Yu-Te Hsieh entitled “High Reliability Housing for a Semiconductor Package,” application Ser. No. 15/175,226, filed Jun. 7, 2016, now pending, the disclosures of each of which are hereby incorporated entirely herein by reference.

### BACKGROUND

### 1. Technical Field

Aspects of this document relate generally to semiconductor packages with dies having sensing areas. More specific implementations involve chip on board packages with image sensors.

### 2. Background Art

Image sensing device packages typically include a cover over a die that includes an image sensor. The cover allows light to interact with the image sensor and corresponding signals from the image sensor are used to create an image corresponding with the incident light. The package is designed to protect the image sensor and related connectors from moisture.

### SUMMARY

Implementations of an image sensor package may include a substrate including a first side and a second side and an image signal processor (ISP) including a first side and a second side. The first side of the ISP may be coupled to the first side of the substrate. Implementations of image sensor packages may include a first mold compound encapsulating the second side of the ISP and an image sensor having a first side and a second side. The first side may be coupled to the first mold compound and the first mold compound may be substantially coextensive with a perimeter of the first side of the image sensor. Implementations of image sensor packages may also include an optically transmissive cover coupled to the second side of the image sensor and a polymeric compound encapsulating a portion of the substrate, the first mold compound, the image sensor, and a portion of the optically transmissive cover.

Implementations of image sensor packages may include one, all, or any of the following:

The package may also include a first plurality of wirebonds coupling the second side of the ISP with the first side of the substrate. The first plurality of wirebonds may be encapsulated by the first mold compound.

The second side of the ISP may be electrically coupled with the substrate through one or more electrical connectors.

The package may also include a second plurality of wirebonds coupling the second side of the image sensor with the first side of the substrate. The second plurality of wirebonds may be encapsulated by the polymeric compound.

The second side of the image sensor may be electrically coupled with the substrate through one or more electrical connectors.

A perimeter of the second side of the ISP may be smaller than a perimeter of the first side of the image sensor.

The entirety of the first side of the image sensor may be directly supported by the first mold compound.

Implementations of an image sensor package may include a substrate having a first side and a second side and an image signal processor (ISP) and an image signal processor (ISP) having a first side and a second side. The first side of the ISP may be coupled to the first side of the substrate. Implementations of the image sensor package may include a first mold compound encapsulating the second side of the ISP. The first mold compound may encapsulate a first plurality of electrical connectors coupled to the first side of the substrate and to the second side of the ISP. Implementations of an image sensor package may include an image sensor having a first side and a second side. The first side of the image sensor may be coupled to the first mold compound and the second side of the image sensor may be electrically coupled to the substrate. Implementations of an image sensor may include an optically transmissive cover coupled to the second side of the image sensor and a polymeric compound encapsulating a second plurality of electrical connectors coupled to the first side of the substrate and the second side of the image sensor. A perimeter of the second side of the ISP may be smaller than a perimeter of the first side of the image sensor and a perimeter of the first side of the image sensor may be substantially the same size as a perimeter of the first mold compound.

Implementations of image sensor packages may include one, all, or any of the following:

The encapsulant may be a liquid encapsulant.

The encapsulant may be a second mold compound.

The image sensor package may also include a plurality of electrical contacts coupled to the second side of the substrate.

The image sensor package may also include a thermally conductive layer coupled between the first side of the substrate and the first side of the ISP.

A thickness of the ISP and a thickness of the image sensor may each be less than 100 micrometers.

The first mold compound may entirely cover the second side, a third side, a fourth side, a fifth side, and a sixth side of the ISP.

Implementations of a method of forming an image sensor package may include die bonding a first side of an image signal processor (ISP) to a first side of a substrate, electrically coupling a second side of the ISP to the first side of the substrate, and forming a first mold compound over the second side of the ISP. The first mold compound may have a flat image sensor mounting surface. Implementations of a method of forming an image sensor package may also include coupling a first side of an image sensor to the flat image sensor mounting surface, electrically coupling a second side of the image sensor with the substrate, electrically coupling a second side of the image sensor with the substrate, coupling an optically transmissive cover to the second side of the image sensor, and encapsulating a polymer material over a portion of the substrate, the first mold compound, the image sensor, and a portion of the optically transmissive cover. The entire first side of the image sensor may be directly coupled to the first mold compound.

Implementations of a method of forming an image sensor package may include one, all or any of the following:

The method may include forming a plurality of electrical contacts to a second side of the substrate.

The flat image sensor mounting surface may be formed by applying die attach film.

The first mold compound may be formed using one of a compression molding technique and a transfer molding technique.

The method may include thinning the ISP, the image sensor, or both the ISP and the image sensor.

A perimeter of the flat image sensor mounting surface may be substantially coextensive with a perimeter of the first side of the image sensor.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a break apart view of a complementary metal-oxide semiconductor (CMOS) image sensor (CIS) ball grid array package;

FIG. 2 is a side view of an implementation a semiconductor package with a housing;

FIG. 3 is a side view of another implementation a semiconductor package with a housing;

FIG. 4 is a side view of another implementation a semiconductor package with a housing having an optics package attachment;

FIGS. 5A-5D show package implementations at various steps of an implementation of a method for making a semiconductor package with a housing;

FIGS. 6A-6D show package implementations at various steps of another implementation of a method for making a semiconductor package with a housing;

FIG. 7 is a cross sectional side view of an illustration of a semiconductor package with a liquid encapsulant;

FIG. 8 is a cross sectional side view of an illustration of a semiconductor package with a mold compound; and

FIGS. 9A-9E illustrates package implementations at various steps of an implementation of a method for making the semiconductor package of either FIG. 7 or FIG. 8.

### DESCRIPTION

This disclosure, its aspects and implementations, are not limited to the specific components, assembly procedures or method elements disclosed herein. Many additional components, assembly procedures and/or method elements known in the art consistent with the intended semiconductor housing packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor housing packages, and implementing components and methods, consistent with the intended operation and methods.

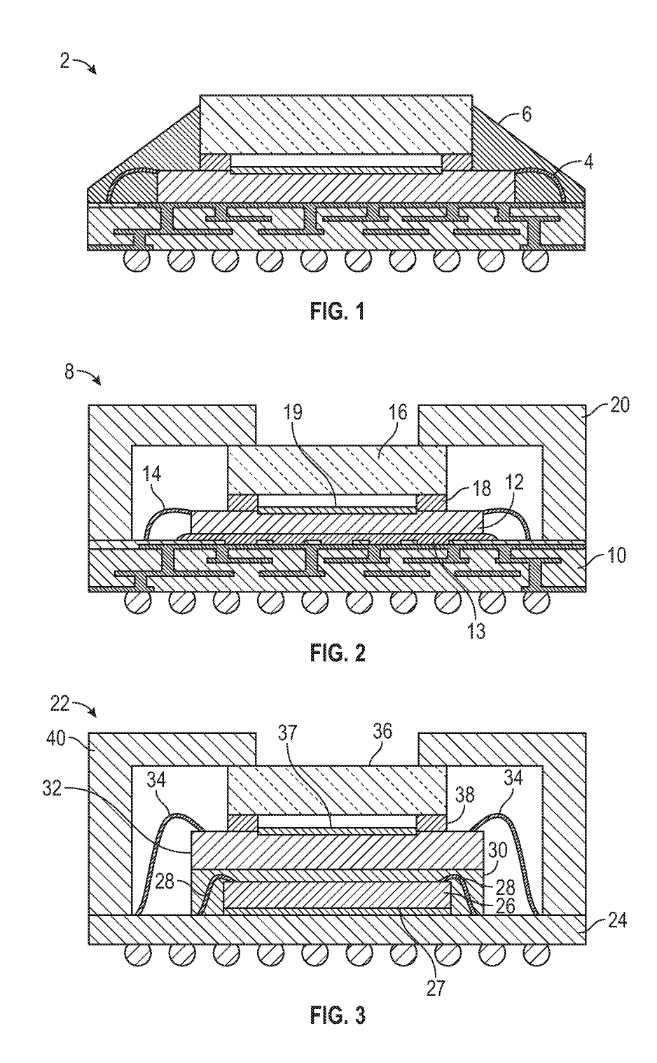

FIG. 1 illustrates a semiconductor package 2 with wire bonding 4 and liquid encapsulation 6. The liquid encapsulation 6 covers and protects the wire bonding 4 area from mechanical damage. A major drawback of the illustrated package 2 is a mismatch that exists between the coefficient of thermal expansion (CTE) of the liquid encapsulation resin and the substrate. The CTE mismatch can cause thermal stress during temperature cycling tests and decreases the reliability of the package.

Referring to FIG. 2, an implementation of a semiconductor package 8 with housing 20 is illustrated. Here, the substrate 10 is coupled to a die 12 by an adhesive 13 and to one or more connectors 14. The connectors 14 may include a wire made out of any electrically conductive material (wirebonds, etc.). The glass lid 16 is coupled to the die 12 by an adhesive 18. The glass lid is positioned over the sensing area 19 of the die 12 and the adhesive 18 is coupled to the die 12 on/at the non-sensing area. The housing 20 has one or more sides and a bottom opening and a top opening. The bottom opening of the housing 20 is mechanically coupled to the substrate 10. The glass lid 16 is coupled under the housing 20 at the top opening. One feature of the housing 20 on the semiconductor packaging 8 over the liquid encapsulation (FIG. 1) is that the housing 20 does not touch the connectors 14. Contact between the housing and the connectors 14 could lead to wire fatigue with wire connectors. Another feature is there is no coefficient of thermal energy mismatch between a liquid encapsulation compound and the die, as there is nothing but air or gas (or vacuum in various implementations) between the housing and the die, which limits any damage to the connectors during temperature cycling.

Referring to FIG. 3, another implementation of a semiconductor package housing 22 is illustrated. A substrate 24 is coupled to a die 26 (first die) by an adhesive 27 and to one or more connectors 28. By non-limiting example the die 26 may be an in-system programming or image signal processing (ISP) die. A mold compound/liquid encapsulant 30 encapsulates the die 26 and connectors 28. The mold 30 is made flat around the die 26 and connectors 28 to enable the coupling of an additional die 32 (second die) to the semiconductor package 22. The additional die 32 is electrically coupled to the substrate 24 through one or more connectors 34. By non-limiting example, the additional die 32 may be a contact image sensor (CIS) die. The additional die 32 may also be coupled directly to the surface of the die 26 by an adhesive. A glass lid 36 is coupled to the additional die 32 using an adhesive 38. The glass lid 36 is positioned over the sensing area 37 of the additional die 32 and the adhesive 38 is coupled to/at the non-sensing area of the additional die 32. A housing 40 is coupled to the substrate 24 at the bottom opening of the housing 40 and over the glass lid 36 at a top opening of the housing 40 using an adhesive.

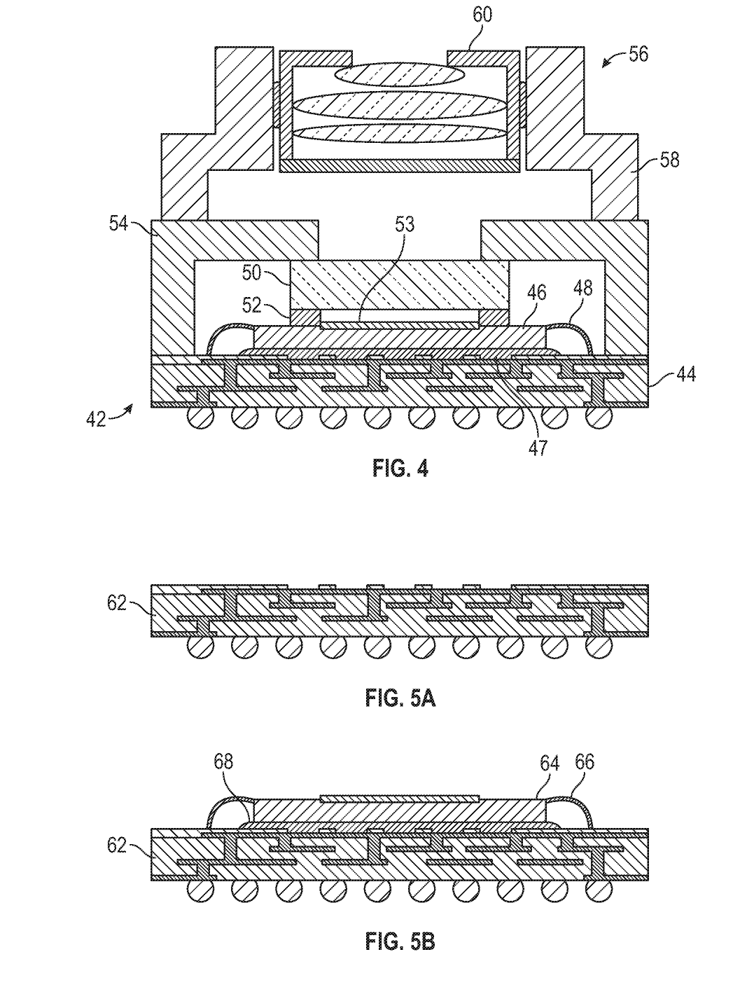

Referring to FIG. 4, another implementation of a semiconductor package 42 with housing 54 having an optics package/unit/assembly 56 attached is illustrated. The substrate 44 is coupled to the die 46 by an adhesive 47 and connectors 48. The glass lid 50 is coupled to the die 46 by an adhesive 52. The glass lid 50 is positioned over the sensing area 53 of the die 46 and the adhesive 52 is coupled to the non-sensing area 53 of the die 46. The substrate 44 is coupled to the housing 54 at the bottom opening. The glass lid 50 is coupled under the housing 54 at the top opening. The flat structure of the housing 54 allows the coupling of a housing of the optics package 56 to the semiconductor package 42. An optics package 56, having a lens housing 58 and one or more lenses 60, may be coupled to the semiconductor package 42 housing 54 in an optical path of the glass lid 50. While in the implementation illustrated, the one or more lenses 60 are located in the optical path directly above the sensing area 53 of the die 46, in other implementations, they may not be directly above the sensing area 53, but may be positioned in other locations, but still in the optical path through the use of other mirrors, lenses, and the like.

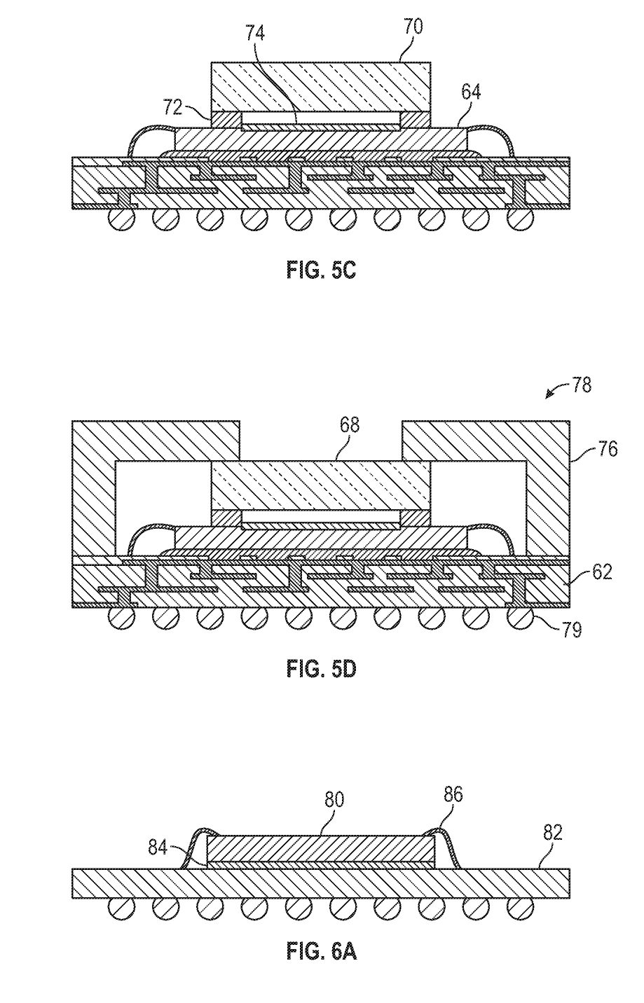

Referring to FIG. 5A-5D, an implementation of a method of manufacturing a semiconductor package like those disclosed in this document is illustrated. FIG. 5A illustrates a substrate 62. By non-limiting example, the substrate 62 may be a multilevel substrate with traces through the levels that connect to the ball grid array, though single level substrates may be used in other implementations, which do not include ball grid arrays (like land grid array substrates). FIG. 5B illustrates coupling one or more die 64 to the substrate 62 and electrically coupling the die to the substrate 62 by an adhesive 68 and one or more connectors 66. FIG. 5C illustrates coupling a glass lid 70 to the die 64 using an adhesive 72. The glass lid 70 is coupled over the sensing area 74 of the die 64. The adhesive 72 is coupled to the non-sensing area of the die 64. By non-limiting example, the sensing area 74 of the die 64 may be a pixel array or the active area of a light emitting diode (LED). In such LED implementations, the sensing area becomes an active area that actively emits light. FIG. 5D illustrates coupling the housing 76 to the semiconductor package 78. In this process, the housing 76 is simultaneously coupled to the substrate 62 at the bottom opening of the housing 76 and over the glass lid 68 at a top opening of the housing 76 using an adhesive. The housing 76 may be made of an opaque material in various implementations, but could also be made of a translucent or transparent material in other implementations. The housing 76 may be formed through one of injection molding, transfer molding and any combination thereof. A ball grid array 79 may be coupled to the opposing side of the substrate 62 where the housing 76 is coupled to the substrate 62 in various implementations.

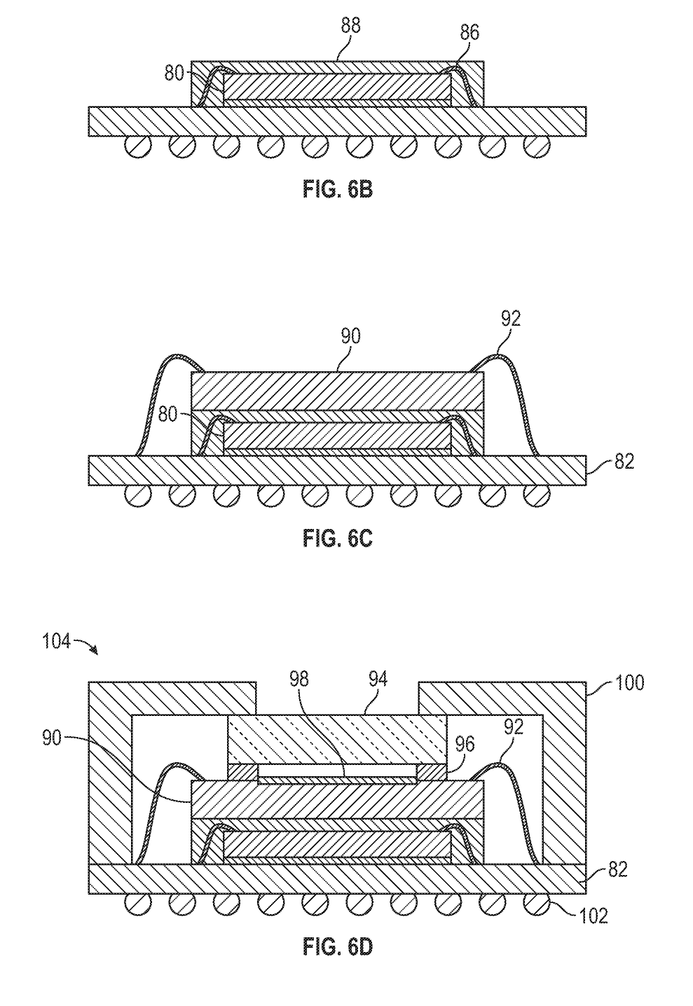

Referring to FIG. 6A-6D, another implementation of a method for manufacturing a semiconductor package like those disclosed herein is illustrated. FIG. 6A illustrates mechanically and electrically coupling a die 80 to a substrate 82 with an adhesive 84 and connectors 86. FIG. 6B illustrates encapsulating the connectors 86 and at least a portion of the die 80 with a mold compound 88. By non-limiting example, the molding may be added by a transfer molding process using a thermal setting (thermoset) polymer material to minimize CTE mismatch. Such polymer materials may also have desirably physical and mechanical properties that may help achieve good reliability performance for the package. FIG. 6C illustrates coupling an additional die 90 to one of the one or more die 80 and electrically coupling the additional die 90 to the substrate 82 with one or more connectors 92.

FIG. 6D illustrates coupling a glass lid 94 to the additional die 90 using an adhesive 96. The glass lid 94 is positioned over the sensing area 98 of the additional die 90. The adhesive 96 is coupled to the non-sensing area of the additional die 90. Then the housing 100 is simultaneously coupled to the substrate 82 at a bottom opening of the housing 100 and over the glass lid 94 at a top opening of the housing 100 using an adhesive. The housing 100 does not touch the connectors 92. A ball grid array 102 may be coupled to the substrate 82. In this implementation, the additional die 90 may be an LED or an image sensor like any disclosed in this document.

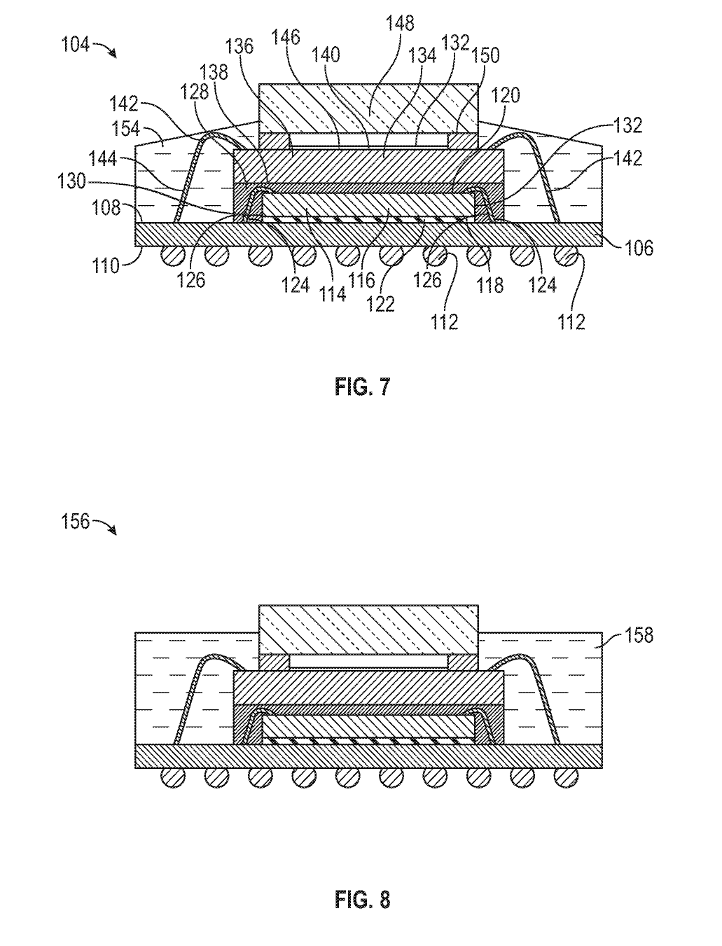

Referring to FIG. 7, a cross sectional side view of a semiconductor package with a liquid encapsulant is illustrated. In various implementations, the package illustrated in FIG. 7 is similar in certain ways with the package illustrated in FIG. 3, with the primary difference being that the package of FIG. 7 does not include a housing over the package but rather includes a liquid encapsulant which covers and protects the semiconductor package. In various implementations, the semiconductor package illustrated in FIG. 7 may be an image sensor package 104. While this application refers to the semiconductor packages as being an image sensor packages, it is understood that in various implementations the semiconductor package may be a package other than an image sensor package and the principles disclosed herein may be used in packaging die other than image sensors. The image sensor package 104 includes a substrate 106. The substrate includes a first side 108 and a second side 110. In various implementations, the second side 110 of the substrate 106 may be coupled to one or more electrical contacts 112 which are configured to electrically couple the image sensor package 104 to an exterior device. In various implementations, and as illustrated by FIG. 7, the one or more electrical contacts 112 may form a ball grid array. In other implementations, the one or more electrical contacts 112 may form a land grid array. In other implementations, the one or more electrical contacts 112 may be a plurality of balls, pins, studs, bumps, or any other electrical contact configured to electrically couple the image sensor package 104 to an exterior device.

The image sensor package 104 includes a first die 114. In various implementations, and as illustrated by FIG. 7, the first die 114 may be an image signal processor (ISP) 116 or a digital signal processor (DSP). The ISP includes a first side 118 and a second side 120. The first side 118 of the ISP 116 is coupled to the first side 108 of the substrate 106. In various implementations, the image sensor package 104 includes a thermal (thermally) conductive layer 122 coupled between the first side 108 of the substrate 106 and the first side 118 of the ISP 116. The thermal conductive layer 122 may include any material of conducting heat, including, by non-limiting example, a solder, a thermally conductive epoxy, a thermal grease, etc. In other implementations, the first side 118 of the ISP 116 may be directly coupled to the first side 108 of the substrate 106 with no thermal conductive layer or other layers between.

As illustrated in FIG. 7, the ISP 116 is electrically coupled to the substrate 106. In particular implementations, the second side 120 of the ISP 116 is electrically coupled with the substrate 106 through one or more electrical connectors 124. In the implementation illustrated by FIG. 7, the one or more electrical connectors 124 may be one or more wirebonds 126 coupling the second side 120 of the ISP with the first side 108 of the substrate 106. In other implementations, the one or more electrical connectors 124 may be one or more clips. In implementations with one or more wirebonds 126 or clips, the wirebonds or clips may be, by non-limiting example, gold, copper, or any other electrically conductive material. In other implementations, rather than wirebonds 126 or clips, the ISP 116 may be electrically coupled to the substrate through one or more through-silicon vias (TSV) formed in the ISP 116 and corresponding pads in the substrate 106 that align with the TSVs. In implementations including a thermal conductive layer 122, coupled between the substrate and an ISP including TSVs, the thermal conductive layer 122 may also be electrically conductive or it may include electrically conductive portions which allow the TSVs of the ISP 116 to be electrically coupled to the substrate 106. In still other implementations, any of the other electrical connectors disclosed in this document could be used to electrically couple the ISP 116 to the substrate 106.

In various implementations, the image sensor package 104 includes a first mold compound 128. The first mold compound may be, by non-limiting example, an epoxy molding compound, an acrylic molding compound, a polymeric molding compound, or any other type of molding or encapsulating compound. In various implementations, as illustrated in FIG. 7, the first mold compound 128 covers the second side 120 of the ISP 116. In particular implementations, the first mold compound 128 is substantially coextensive in size with the second side of the ISP. In other implementations, the first mold compound 128 encapsulates the second side 120 of the ISP 116. In such implementations, the first mold compound 128 may extend fully along and entirely cover the third side 130, a fourth side 132, a fifth side, and a sixth side of the ISP, thus fully covering the ISP 116. In implementations including one or more wirebonds, the one or more wirebonds may be encapsulated by the first mold compound 128.

Still referring to FIG. 7, the image sensor package 104 includes a second die 134. The second die 134 may be an image sensor 136. In various implementations, the image sensor 136 is a contact image sensor (CIS), though many other image sensor types may be employed in various implementations. The image sensor 136 includes a first side 138 and a second side 140. The first side 138 of the image sensor 136 may be coupled to the first mold compound 128. In various implementations, a perimeter of the first side 138 of the image sensor 136 may be substantially coextensive with a perimeter of the first mold compound. In other implementations, the perimeter of the first side 138 of the image sensor 136 may be smaller than the first mold compound. In either situation, the entirety of the first side 138 of the image sensor 136 is directly supported by the first mold compound 128. In various implementations, a perimeter of the second side 120 of the ISP 116 may be smaller than the perimeter of the first side 138 of the image sensor 136. In such implementations where the perimeter of the second side 120 of the ISP 116 is smaller than the perimeter of the first side 139 of the image sensor 136, absent a mold compound, the image sensor 136 would extend past the second side of the ISP and create an overhang. By including the first mold compound 128, the image sensor can be completely supported and result in a more reliable and structurally secure image sensor package 104 because any unsupported overhang of the image sensor is eliminated.

The image sensor 136 is electrically coupled to the substrate 106. In particular implementations, the second side 140 of the image sensor 136 is electrically coupled with the substrate 106 through one or more electrical connectors 142. This allows for an image sensing area 146 located on the second side 140 of the image sensor 136 to be electrically coupled to the substrate 106 and/or the ISP 116. In the implementation illustrated in FIG. 7, the one or more electrical connectors 142 may be one or more wirebonds 144 coupling the second side 140 of the image sensor with the first side 108 of the substrate 106. In other implementations, the one or more electrical connectors 142 may be one or more clips. In implementations with one or more wirebonds 144 or clips, the wirebonds or clips may be, by non-limiting example, gold, copper, or any other electrically conductive material. In other implementations, rather than wirebonds 144 or clips, the image sensor 136 may be electrically coupled to the substrate through one or more through-silicon vias (TSV) formed in the image sensor 136 and aligned with pillars coupled with the substrate or pads formed on the top surface of the first mold compound 128. In some implementations, the TSVs in the image sensor 136 may be electrically coupled to the substrate through the TSVs in the ISP 116. In implementations with TSVs in the image sensor 136 and/or the ISP 116, the first mold compound 128 may include electrically conductive portions or electrical routing which electrically couples the TSVs of the image sensor 136 to the TSVs of the ISP 116. In still other implementations, any other electrical connectors disclosed in this document could be used to electrically couple the image sensor 136 to the substrate 106.

The image sensor package 104 may include an optically transmissive cover 148. The optically transmissive cover 148 may be transparent or translucent. In various implementations, the optically transmissive cover 148 may be glass or any other optically transmissive material capable of transmitting a desired wavelength of light. The optically transmissive cover 148 may be coupled to the second side 140 of the image sensor 136 and over the image sensing area 146. In various implementations, an adhesive 150 may separate the image sensor from the optically transmissive cover 148, thus creating a cavity 152 between the image sensor, the optically transmissive cover, and the adhesive 150. In other implementations, a plurality of dams may be placed between the optically transmissive cover 148 and the image sensor 136. The cavity 152 may be hermetically or substantially hermetically sealed, protecting the image sensing area 146 and preventing the ingress of contaminants and moisture within the cavity.

Still referring to FIG. 7, the image sensor package 104 includes a polymeric compound 154. The polymeric compound 154 may encapsulate a portion of the substrate 106, the first mold compound 128, the image sensor 136, and a portion of the optically transmissive cover 148. In implementations where the image sensor package 104 includes wirebonds 144, or other electrical connectors such as clips, electrically coupling the second side 140 of the image sensor 136 with the first side 108 of the substrate 106, the polymeric compound 154 may encapsulate the wirebonds or other electrical connectors. In various implementations, and as illustrated by FIG. 7, the polymeric compound 154 may be a liquid encapsulant, though any other mold compound or encapsulant disclosed herein may be used.

Referring to FIG. 8, a cross sectional side view of an illustration of a semiconductor package with a mold compound is illustrated. In various implementations, the semiconductor package is an image sensor package 156. The image sensor package 156 may be the same as the image sensor package 104 of FIG. 7, with the only difference being that the polymeric compound covering the outer portion of the package is a second molding compound 158 rather than a liquid encapsulant. The second molding compound may be any type of molding compound disclosed herein. Having the polymeric compound encapsulate the image sensor package as illustrated in FIGS. 7 and 8 may increase the reliability of the package.

In various implementations, the image sensor packages illustrated in FIGS. 7 and 8 provide a small footprint as both the ISP and the image sensor are combined in a single package. In various implementations, the ISP and/or the image sensor may be thinned to less than 100 micrometers each. Having the ISP and the image sensor in the same package may also increase the image signal performance as the ISP is in close proximity to the image sensor and the proximity results in minimizing the length of trace interconnects between the ISP and the image sensor.

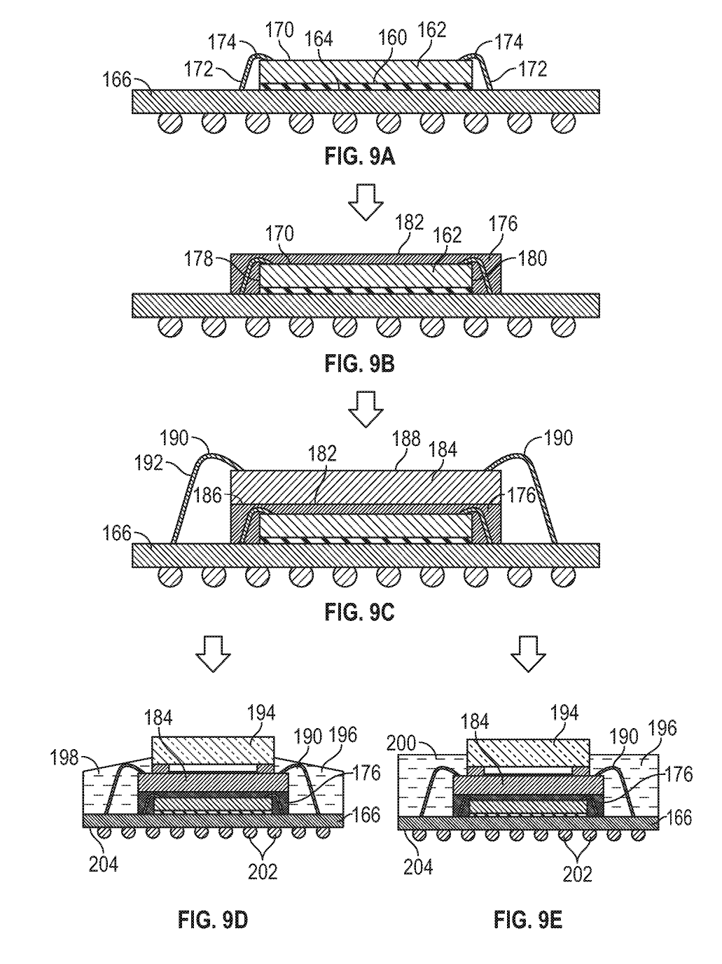

Referring to FIGS. 9A-9E, package implementations at various steps of an implementation of a method for making the semiconductor package of either FIG. 7 or FIG. 8 is illustrated. Referring to FIG. 9A, an implementation of a method for forming a semiconductor package, specifically an image sensor package, includes die bonding a first side 160 of an ISP 162 to a first side 164 of a substrate 166. In various implementations, the ISP 162 is bonded to the substrate using a chip-on-board (COB) packaging method. In various implementations, the ISP may be directly bonded to the substrate using, by non-limiting example, a die attach film, a liquid epoxy resin, or another adhesive type. In other implementations, and as illustrated by FIG. 9A, the method may include forming a thermal conductive layer 168 between the ISP 162 and the substrate 166. The thermal conductive 168 layer may be any type of thermal conductive layer disclosed herein. The thermal conductive layer 168 may be first coupled to the first side 160 of the ISP 162 or the first side 164 of the substrate 166 before the substrate is coupled to the ISP. In various implementations, the method may include thinning the ISP prior to die attach or afterward using a die grinding, polishing, or lapping process. In such implementations, the ISP may be thinned to less than 100 micrometers in thickness.

In various implementations, the method for making the image sensor package includes electrically coupling the ISP 162 to the first side 164 of the substrate 166. In particular implementations, the method includes electrically coupling the second side 170 of the ISP 162 to the first side 164 of the substrate 166. The ISP 162 is electrically coupled to the substrate 166 using a first plurality of electrical connectors 172. Though wirebonds 174 are illustrated herein as the electrical connectors 172, it is understood that any electrical connector disclosed herein could be used to electrically couple the ISP 162 to the substrate 166.

Referring to FIG. 9B, the implementation of a method for making an image sensor package may include forming a first mold compound 176 over the second side 170 of the ISP 162. In various implementations the first mold compound 176 only covers the second side of the ISP 162, however, in other implementations the first mold compound also extends along a third side 178, a fourth side 180, a fifth side, and a sixth side of the ISP, thus fully covering the ISP. The first mold compound 176 may also fully encapsulate the electrical connectors 172, as illustrated in FIG. 9B. The first mold compound may be any type disclosed herein and may be applied using, by non-limiting example, compression molding techniques, transfer molding techniques, or other mold application techniques. The first mold compound 176 may include/form a flat image sensor mounting surface 182.

Referring to FIG. 9C, the implementation of a method for making an image sensor package includes coupling a first side 186 of an image sensor 184 to the flat image sensor mounting surface 182. In various implementations, the image sensor 184 is bonded to the first mold compound 176 using a COB packaging method. In various implementations, the entire first side 186 of the image sensor 184 is directly coupled to and fully supported by the first mold compound 176. In such implementations, a perimeter of the flat image sensor mounting surface 182 may be substantially coextensive with a perimeter of the first side 186 of the image sensor 184. In other such implementations, the perimeter of the flat image sensor mounting surface 182 may be larger than the perimeter of the first side 186 of the image sensor 184. In various implementations, the flat image sensor mounting surface 182 is made flat by applying a die attach film thereon. The image sensor 184 may be attached to the first mold compound 176 via the die attach film. The die attach film may prevent the image sensor from shifting before the die attach film is cured. In various implementations, the method may include thinning the image sensor using any of the methods disclosed herein. In such implementations, the image sensor may be thinned to less than 100 micrometers in thickness.

The implementation of a method for making an image sensor package may also include electrically coupling a second side 188 of the image sensor 184 with the substrate 166. The image sensor 188 is electrically coupled to the substrate 166 using a second plurality of electrical connectors 190. Though wirebonds 192 are illustrated as the electrical connectors 190, it is understood that any electrical connector disclosed herein could be formed within the image sensor package and used to electrically couple the image sensor 184 to the substrate 166.

Referring to FIGS. 9D and 9E, various implementations of a method for making an image sensor package may also include coupling an optically transmissive cover 194 to the second side 188 of the image sensor 184. The optically transmissive cover may be any type of optically transmissive cover disclosed herein. In various implementations, the method of making the image sensor package includes forming a dam wall or an adhesive between the optically transmissive layer 194 and an image sensing area of the image sensor. In such implementations, the dam wall or adhesive, the optically transmissive cover, and the image sensor may form a cavity that houses the image sensing area of the image sensor. The adhesive used to couple the optically transmissive cover 194 to the image sensor may be a liquid epoxy resin or any other type of adhesive.

Various implementations of methods for forming an image sensor package may include encapsulating a polymer material 196 over a portion of the substrate 166, the first mold compound 176, the image sensor 184, and a portion of the optically transmissive cover 194. In such implementations, the polymer material 196 may cover the interfaces between the substrate 166 and the first mold compound 176, the interfaces between the first mold compound and the image sensor 184, and the interfaces between the image sensor and the optically transmissive cover 194. In various implementations, the polymer material 196 may fully encapsulate the electrical connectors 190. In various implementations, and as illustrated in FIG. 9D, the polymer material 196 may be a liquid encapsulant 198. In such implementations, the liquid encapsulant may be a liquid epoxy resin. In other implementations, as illustrated by FIG. 9E, the polymer material 196 may be a second mold compound 200. The second mold compound 200 may be any type of mold compound disclosed herein and may be applied using any mold application technique disclosed herein.

Various implementations of forming an image sensor package may include forming one or more electrical contacts 202 to the second side 204 of the substrate 166. In various implementations, the electrical contacts 202 may be formed near the beginning, end, or at any other point in the process of forming the image sensor package. The one or more electrical contacts 202 may be any type of electrical contact disclosed herein. In FIGS. 9D and 9E they are illustrated as being a ball grid array.

In places where the description above refers to particular implementations of semiconductor packages with housing and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. An image sensor package comprising:
a substrate comprising a first side and a second side;
an image signal processor (ISP) comprising a first side and a second side, wherein the first side of the ISP is coupled to the first side of the substrate;
a first mold compound encapsulating the second side of the ISP;
an image sensor comprising a first side and a second side, wherein the first side is coupled to the first mold compound, the first mold compound substantially coextensive with a perimeter of the first side of the image sensor;
an optically transmissive cover coupled to the second side of the image sensor; and
a polymeric compound encapsulating a portion of the substrate, the first mold compound, the image sensor, and a portion of the optically transmissive cover.

2. The package of claim 1, further comprising a first plurality of wirebonds coupling the second side of the ISP with the first side of the substrate, wherein the first plurality of wirebonds is encapsulated by the first mold compound.

3. The package of claim 1, wherein the second side of the ISP is electrically coupled with the substrate through one or more electrical connectors.

4. The package of claim 1, further comprising a second plurality of wirebonds coupling the second side of the image sensor with the first side of the substrate, wherein the second plurality of wirebonds is encapsulated by the polymeric compound.

5. The package of claim 1, wherein the second side of the image sensor is electrically coupled with the substrate through one or more electrical connectors.

6. The package of claim 1, wherein a perimeter of the second side of the ISP is smaller than a perimeter of the first side of the image sensor.

7. The package of claim 1, wherein the entirety of the first side of the image sensor is directly supported by the first mold compound.

8. An image sensor package comprising:
a substrate comprising a first side and a second side;
an image signal processor (ISP) comprising a first side and a second side, wherein the first side is coupled to the first side of the substrate;
a first mold compound encapsulating the second side of the ISP, wherein the first mold compound encapsulates a first plurality of electrical connectors coupled to the first side of the substrate and to the second side of the ISP;
an image sensor comprising a first side and a second side, wherein the first side is coupled to the first mold compound and the second side is electrically coupled to the substrate;
an optically transmissive cover coupled to the second side of the image sensor; and
a polymeric compound encapsulating a second plurality of electrical connectors coupled to the first side of the substrate and the second side of the image sensor;
wherein a perimeter of the second side of the ISP is smaller than a perimeter of the first side of the image sensor; and
wherein a perimeter of the first side of the image sensor is substantially the same size as a perimeter of the first mold compound.

9. The package of claim 8, wherein the encapsulant is a liquid encapsulant.

10. The package of claim 8, wherein the encapsulant is a second mold compound.

11. The package of claim 8, further comprising a plurality of electrical contacts coupled to the second side of the substrate.

12. The package of claim 8, further comprising a thermal conductive layer coupled between the first side of the substrate and the first side of the ISP.

13. The package of claim 8, wherein a thickness of the ISP and a thickness of the image sensor are each less than 100 micrometers.

14. The package of claim 8, wherein the first mold compound entirely covers the second side, a third side, a fourth side, a fifth side, and a sixth side of the ISP.

15. A method of forming an image sensor package comprising:
die bonding a first side of an image signal processor (ISP) to a first side of a substrate;
electrically coupling a second side of the ISP to the first side of the substrate;
forming a first mold compound over the second side of the ISP, the first mold compound comprising a flat image sensor mounting surface;
coupling a first side of an image sensor to the flat image sensor mounting surface, wherein the entire first side of the image sensor is directly coupled to the first mold compound;
electrically coupling a second side of the image sensor with the substrate;
coupling an optically transmissive cover to the second side of the image sensor; and
encapsulating a polymer material over a portion of the substrate, the first mold compound, the image sensor, and a portion of the optically transmissive cover.

16. The method of claim 15, further comprising forming a plurality of electrical contacts to a second side of the substrate.

17. The method of claim 15, wherein the flat image sensor mounting surface is formed by applying die attach film.

18. The method of claim 15, wherein the first mold compound is formed using one of a compression molding technique and a transfer molding technique.

19. The method of claim 15, further comprising thinning one of the ISP, the image sensor, and both the ISP and the image sensor.

20. The method of claim 15, wherein a perimeter of the flat image sensor mounting surface is substantially coextensive with a perimeter of the first side of the image sensor.
